(19) United States
(12) Patent Application Publication
(10) Pub. No.: US 2008/0242003 A1
(43) Pub. Date: Oct. 2, 2008

(54) INTEGRATED CIRCUIT DEVICES WITH INTEGRAL HEAT SINKS

(75) Inventors: You Chye HOW, Melaka (MY); Shee Min YEONG, Melaka (MY); Seong Mun CHAN, Ipoh (MY); Wee Khim TENG, Kuala Terengganu (MY)

Correspondence Address: Beyer Law Group LLP, P.O. BOX 1687, Cupertino, CA, 95015-1687, US

(73) Assignee: NATIONAL SEMICONDUCTOR CORPORATION, Santa Clara, CA (US)

(21) Appl. No.: 11/691,371

(22) Filed: Mar. 26, 2007

(51) Int. Cl. H01L 21/00

(52) U.S. Cl. 438/122

(57) ABSTRACT

A method for forming integral heat sinks on back surfaces of integrated circuit devices at wafer level is described. A first metallic layer is deposited over the back surface of a wafer. A second metallic layer is deposited over the first metallic layer. Optionally, a third metallic layer is deposited over the second metallic layer. The first metallic layer, the second metallic layer, and optionally the third metallic layer form the integral heat sink for the wafer. When the wafer is diced into multiple semiconductor devices, each semiconductor device has an integral heat sink formed on its back surface that includes the first metallic layer, the second metallic layer, and optionally the third metallic layer. Optionally, each semiconductor device is connected to a lead frame via solder bumps or bonding wires to form an integrated circuit (IC) package.

### FIELD OF THE INVENTION

The present invention generally relates to the packaging of integrated circuit (IC) devices. More particularly, the present invention relates to forming an integral heat sink on the back surface of the die.

### BACKGROUND OF THE INVENTION

There are a number of conventional processes for packaging integrated circuit devices. Many packaging techniques use a lead frame that has been stamped or etched from a metal sheet to provide electrical interconnects to external devices. A die is electrically connected to portions of the lead frame via bonding wires, solder bumps, or other suitable electrical connections. Generally, the die, the lead frame and bonding wires or solder bumps are then encapsulated in a mold while leaving selected portions of the lead frame exposed to facilitate electrical connection to external devices.

Because the IC devices may become hot while in operation, sometimes a heat sink is soldered or glued to the die to help absorb and dissipate heat from the die. Efficient heat sinks are important to IC devices, because faster device cooling rate generally leads to better device performance and stability.

Although existing heat-sinks techniques work well, there are continuing efforts to develop even more efficient designs and methods for dissipating heat for the IC devices.

### SUMMARY OF THE INVENTION

Broadly speaking, the present invention relates to the formation of an integral heat sink on the back surface of a die. In a separate aspect, a packaging system that connects the die, along with its integral heat sink, to a lead frame via solder bumps or bonding wires is described.

In one embodiment, a wafer level method for forming integral heat sinks on the back surface of IC devices is described. The method comprises depositing a first metallic layer over the back surface of a wafer, depositing a second metallic layer over the first metallic layer, and optionally depositing a third metallic layer over the second metallic layer. The plurality of metallic layers form a heat sink that is integrally formed on the back surface of the wafer. When the wafer is diced into multiple semiconductor devices, each semiconductor device has an integral heat sink that includes the plurality of metallic layers formed on the back surface of the die.

In some preferred embodiments, the first layer of the heat sink is formed by sputtering and the second layer is a substantially thicker mass layer formed at least in part by electroplating. In various implementations, a seed layer of the second metallic material may be deposited by sputtering prior to the electroplating. In some embodiments the first metallic layer may be an adhesion layer formed from a material such as titanium, titanium-tungsten, or nickel-vanadium; the thicker, electroplated second metallic layer may be formed from copper or aluminum. Since both copper and aluminum are susceptible to corrosion, in many applications it is desirable to also provide a non-corrosive (or less corrosive) protective layer formed from a material such as titanium, titanium-tungsten, or nickel-vanadium over the mass layer. The protective layer does not need to be particularly thick and therefore may be formed by sputtering in many applications.

The thicknesses of the various layers may vary widely based on the needs of a particular design. By way of example, thickness under 2000 angstroms are suitable for the adhesive and protective layers. Thickness in the range of approximately 10,000 to 100,000 angstroms work well for the mass layer.

In another embodiment, an integrated circuit (IC) package that incorporates a die having an integral heat sink is described. The IC package comprises a semiconductor device with an integral heat sink that is connected to a lead frame via solder bumps or bonding wires. At least portions of the semiconductor device, the lead frame, and solder bumps or bonding wires are encapsulated in an encapsulant, such as a molding material. The outer layer of the metallic material that forms the integral heat sink is exposed to the environment, thus conducting heat away from the die.

These and other features, aspects, and advantages of the invention will be described in more detail below in the detailed description and in conjunction with the following figures.

### BRIEF DESCRIPTION OF THE DRAWINGS

For a better understanding of the invention, reference should be made to the following detailed description taken in conjunction with the accompanying drawings, in which:

FIG. 1 illustrates the active surface of a wafer with multiple solder bumps formed thereon.

FIG. 2 is a flowchart of a method for forming integral heat sinks on back surfaces of integrated circuit devices at wafer level.

FIGS. 3A-3H illustrate the steps of forming an integral heat sink on the back surface of a wafer.

FIGS. 4A-4C illustrate a representative lead frame panel.

FIG. 5 is a flow chart of a method for packaging a semiconductor device with an integral heat sink on a lead frame.

FIGS. 6A-6C illustrate the steps of packaging a semiconductor device with an integral heat sink on a lead frame.

Like reference numerals refer to corresponding parts throughout the drawings.

### DETAILED DESCRIPTION OF THE DRAWINGS

The present invention generally relates to the packaging of integrated circuit (IC) devices. More specifically, the present invention relates to forming an integral heat sink on the back surface of the die.

In the following description, numerous specific details are set forth to provide a thorough understanding of the present invention. It will be apparent, however, to one skilled in the art that the present invention may be practiced without some or all of these specific details. In other instances, well known process steps have not been described in detail in order to avoid unnecessary obscuring of the present invention.

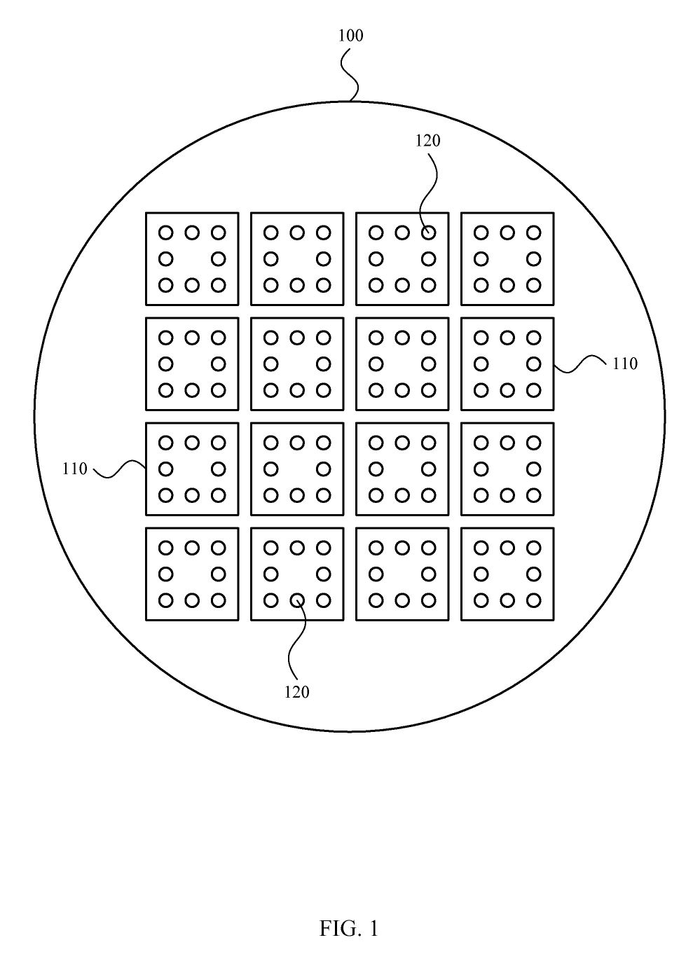

FIG. 1 illustrates the active surface of a wafer 100 with multiple solder bumps 120 formed thereon. The wafer 100 is formed from a semiconductor material, such as silicon. The wafer 100 includes a multiplicity of dice 110. In the diagrammatic illustration, only a few dice are shown. However, as will be appreciated by those familiar with the art, state of the art wafers tend to have on the order of hundreds, to thousands or tens of thousands of dice formed therein and it is expected that even higher device densities will be attained in future wafers. Generally, each die 110 on the wafer 100 will have a number of I/O pads (often referred to as bond pads) formed thereon. In flip chip devices, underbump metallization stacks may be formed on the bond pads to support solder bumps 120 that are mounted directly over the I/O pads. In other devices, the solder bumps may be redistributed relative to the bond pads.

According to an alternative embodiment, bonding wires may be used to connect each individual IC device to a lead frame during the packaging step. In this case, one end of each bonding wire is thermosonically welded to an associated bond pad and the other end is secured to the lead frame or other suitable structure. The bonding wires are typically formed from gold but may be formed from other conductive materials such as aluminum or copper.

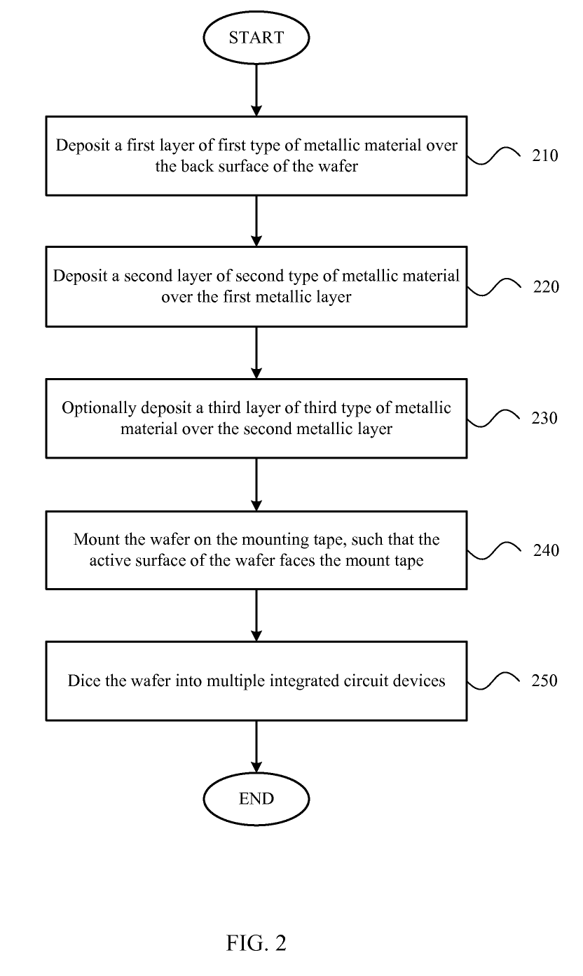

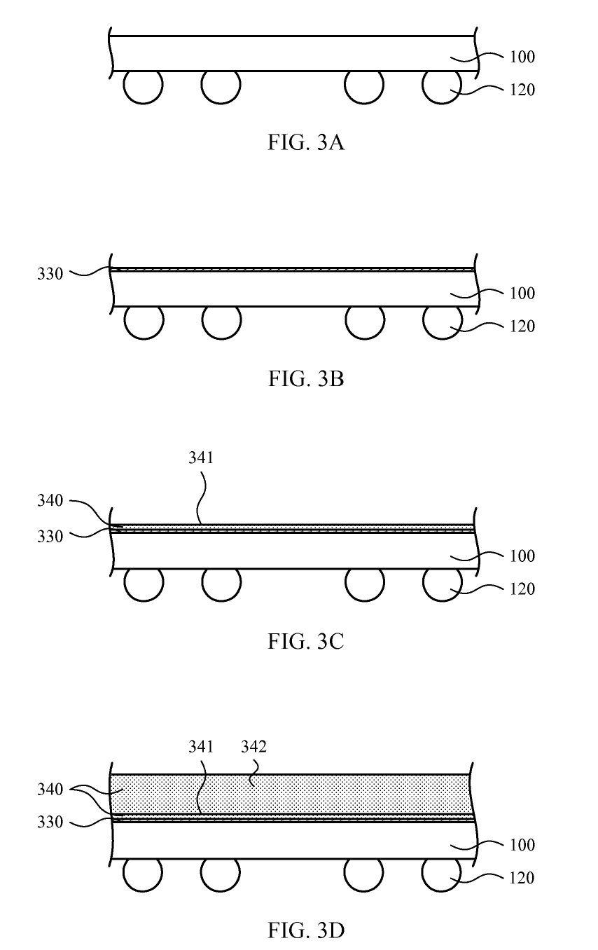

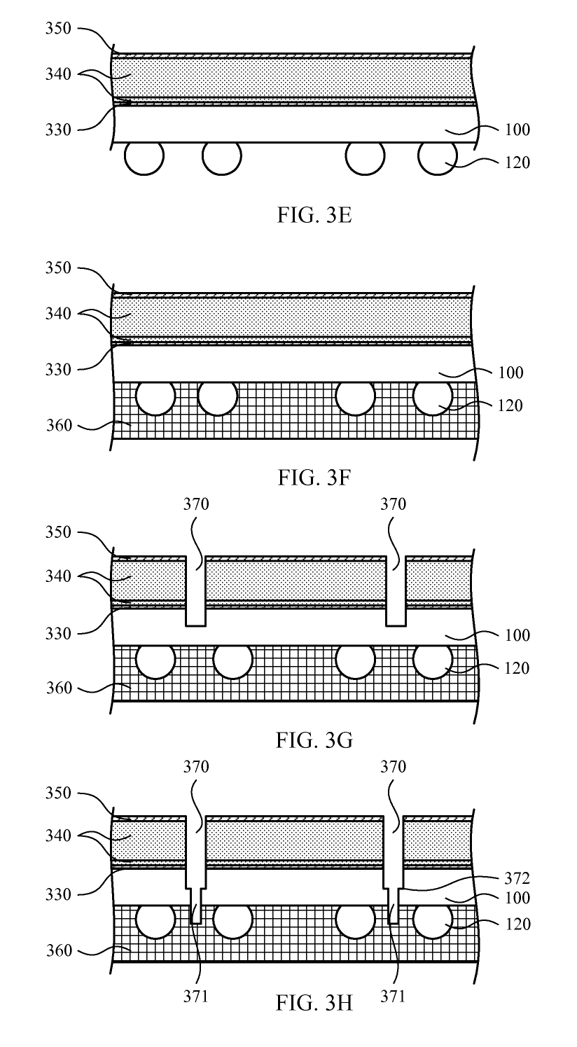

FIG. 2 is a flowchart illustrating a method for forming integral heat sinks on back surfaces of integrated circuit devices at the wafer level in accordance with one embodiment of the invention. Steps of FIG. 2 correspond to FIGS. 3A-3H, which illustrate the steps of forming an integral heat sink on the back surface of a wafer. These steps are applied to the type of wafer 100 illustrated in FIG. 1.

First, a first layer of metallic material is deposited over the back surface of the wafer (step 210 of FIG. 2). FIG. 3A illustrates a cross-section of a portion of the wafer 100 with multiple solder bumps 120 formed on its active surface. By way of illustration, FIG. 3A shows the portion of the wafer 100 with its active surface facing downward.

FIG. 3B illustrates a cross-section of the portion of the wafer 100 with one layer of metallic material 330 deposited over its back surface. According to one embodiment, the first metallic layer 330 is sputtered over the back surface of the wafer 100. Sputtering is a physical process commonly used for thin-film deposition. During sputtering process, atoms in a solid target material are ejected into the gas phase due to bombardment of the material by energetic ions.

This first layer of metallic material 330 helps adhere subsequent layers of metallic materials to the wafer 100. By way of example, metallic materials such as titanium, titanium-tungsten, or nickel-vanadium work well as the adhesion layer. The thickness of the first metallic layer may vary widely based on the needs of a particular application. By way of example, in the described embodiment thicknesses in the range of approximately 100 to 900 ångströms work well. Preferably, the first metallic layer 330 covers the entire back surface of the wafer 100.

Next, a second layer of metallic material is deposited over the first layer of metallic material (step 220 of FIG. 2). FIGS. 3C and 3D illustrate cross-sections of the portion of the wafer 100 with two layers of metallic material 330, 340 deposited over its back surface. According to one embodiment, depositing the second layer of metallic material 340 may be done in two steps. First, a thin seed layer of the second metallic material 341 is sputtered over the first layer of metallic material 330. This step is illustrated in FIG. 3C. By way of example, thicknesses in the range of approximately 1,000 to 1,500 ångströms work well for the seed layer (although it should be appreciated that either thicker or thinner seed layers may be used as well).

Second, a thick layer of the second metallic material 342 is electroplated over the thin layer 341. Together, the thin layer 341 and the thick layer 342 form the second layer of metallic material 340. Platting is a surface-covering technique in which a metal is deposited onto a conductive surface. Platting is more cost-effective than sputtering, and is generally preferred when depositing a thick layer of metallic material. This step is illustrated in FIG. 3D. By way of example, in the described embodiment the thick layer of second metallic material 342 has thicknesses in the range of approximately 10,000 to 50,000 ångströms so that the total thickness of the second metallic layer 340 is in the range of approximately 10,000 to 60,000 ångströms.

A variety of different materials may be used as the second (mass) layer. By way of example, metallic materials such as copper or aluminum work well as the second layer 340. Preferably, the second metallic layer 340 covers the entire first metallic layer 330.

Next, a third layer of metallic material is deposited over the second layer of metallic material (step 230 of FIG. 2). FIG. 3E illustrates cross-section of the portion of the wafer 100 with three layers of metallic material 330, 340, 350 deposited over its back surface. According to one embodiment, the third metallic layer 350 is sputtered over the second metallic layer 340.

This third layer of metallic material 350 helps protect the second layer of metallic material 340 from corrosion. By way of example, non-corrosive, or minimally corrosive metallic materials such as titanium, titanium-tungsten, or nickel-vanadium work well as the protective layer. In the described embodiment this third metallic layer has thicknesses in the range of approximately 1,000 to 1,500 ångströms. Preferably, the third metallic layer 350 covers the entire second metallic layer 340.

According to an alternative embodiment, no protective layer is deposited over the mass (second) layer of metallic material. In this case, the second metallic layer is exposed and therefore, depending on the material used, may be susceptible to corrosion. However, in many situations an entity that mounts the described die or package in a larger system may have the ability to readily remove or otherwise handle such corrosion and therefore corrosion may not be a particular concern in some applications.

The first metallic layer 330, the second metallic layer 340, and (when present) the third metallic layer 350 together form an integral heat sink on the back surface of the wafer 100.

After the integral heat sink has been formed, the wafer may be further processed and diced in a conventional manner. In the illustrated embodiment, the wafer is mounted on a mounting tape, such that the active surface of the wafer faces the mounting tape (step 240 of FIG. 2). FIG. 3F illustrates cross-section of the portion of the wafer 100 mounted on the mounting tape 360. The wafer 100 is now ready to be diced into individual IC devices (step 250 of FIG. 2). After dicing, each individual IC device has an integral heat sink formed in its back surface.

The wafer may be diced in a variety of manners. FIGS. 3G and 3H are sequential diagrammatic cross-sectional views of a portion of the wafer 100 during a suitable dicing operation. In the illustrated embodiment, the dicing of the wafer 100 is a two-step process. First, a relatively wider cut 370 is made from the back side of the wafer partially through the wafer 100. This initial cut extends completely through the heat sink (i.e., layers 330, 340, 350) and partially through the underlying semiconductor material. This step is illustrated in FIG. 3G. By way of example, the wider cut 370 may have a width in the range of approximately 1 to 2 mils (1 mil=1.0×10⁻³ inch=25.4 microns; 1 micron=1.0×10⁻⁶ meter) and may extend approximately 40% to 60% through the wafer 100.

Second, a narrower cut 371 is made completely through the remaining wafer 100. This step is illustrated in FIG. 3H. By way of example, the thinner cut 371 may have a width in the range of approximately 0.8 to 1 mil. The step-like transitional point 372 from the wider cut 370 to the thinner cut 371 forms a locking mechanism, which may be utilized during the subsequent packaging step. At this point, the wafer is diced into multiple IC devices, and each IC device is ready to be packaged.

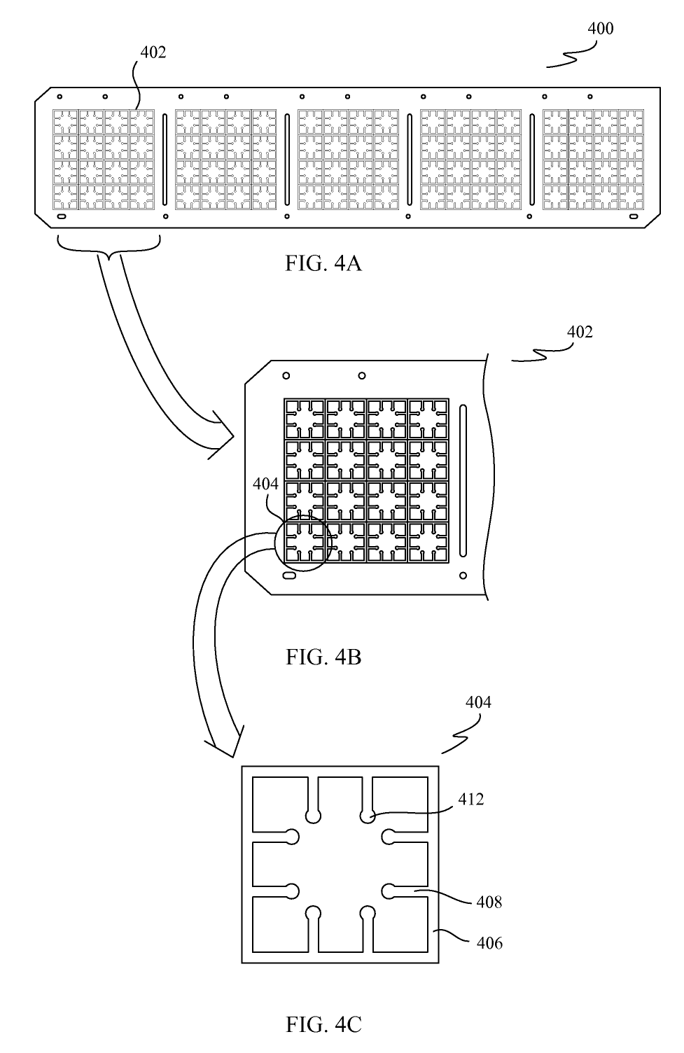

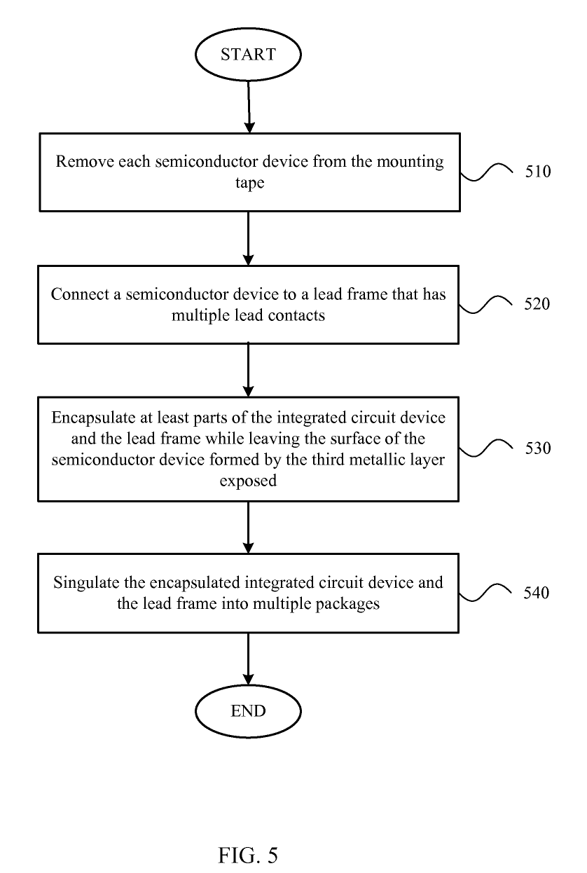

In one embodiment, the described dice with integral heat sinks are used in a flip chip on lead (FLOP) style packages. FIGS. 4A-4C illustrate a representative lead frame panel 400 suitable for use in packaging integrated circuits according to various embodiments of the present invention.

FIG. 4A illustrates a diagrammatic top view of a lead frame panel 400 arranged in the form of a strip. The lead frame panel 400 can be configured as a metallic structure with a number of two-dimensional arrays 402 of device areas. As illustrated in the successively more detailed FIGS. 4B-4C, each two-dimensional array 402 includes a plurality of device areas 404, each configured for use in a single IC package, and each connected by a matrix of fine tie bars 406. During packaging, one or more semiconductor dice are affixed to each device area 404, where they may then be subjected to electrical connection, encapsulation, and singulation processes, yielding individual IC packages.

In order to facilitate these processes, each device area 404 includes a plurality of leads 408, each supported at one end by the tie bars 406. As illustrated in FIG. 4C, the leads 408 include conductive solder pads 412 to provide conductive contact regions to electrically connect the leads to associated solder bumps or bonding wires on the die. Although a specific lead frame panel arrangement 400 has been described and illustrated, the described invention may be applied to an extremely wide variety of other lead frame panels or strip configurations as well.

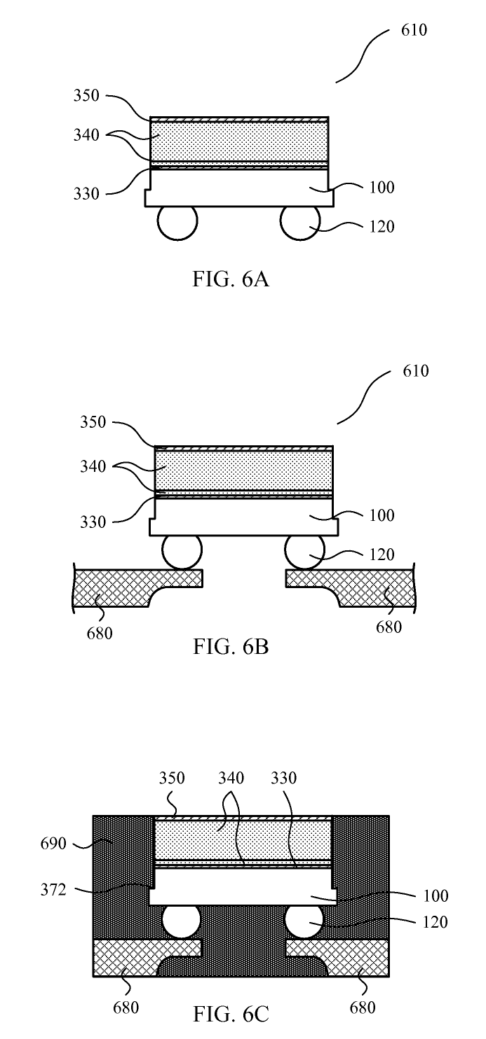

FIG. 5 is a flow chart of a method for packaging a semiconductor device with an integral heat sink on a lead frame. Steps of FIG. 5 correspond to FIGS. 6A-6C, which illustrate the steps of packaging a semiconductor device with an integral heat sink on a lead frame.

First, each semiconductor device is removed from the mounting tape (step 510 of FIG. 5). In some embodiments, a UV releasable mounting tape may be used and in such embodiments, the mounting tape may be exposed to ultra-violet (UV) lighting to help release the individual semiconductor devices. FIG. 6A illustrates cross-section of a semiconductor device 610 with an integral heat sink 330, 340, 350 formed on the back surface of its die 100 and multiple solder bumps 120 formed on the active surface of its die 100. This is one of the semiconductor devices resulted from dicing the wafer during step 250 of FIG. 2.

Next, the semiconductor device is connected to a lead frame (step 520 of FIG. 5). FIG. 6B illustrates the semiconductor device 610 shown in FIG. 6A being connected to a lead frame 680 via the solder bumps 120. According to one embodiment, the semiconductor device 610 is placed on top of the lead frame 680 with the active surface of its die 100 facing downward and each of its solder bumps 120 in contact with a corresponding lead contact. To form a permanent connection, the solder bumps 120 may be reflowed by placing the semiconductor device 610 and the lead frame 680 in an oven. Heating causes the solder bumps 120 to reflow, and after the solder bumps 120 cool down, a permanent bonding between the IC device and the lead frame is formed.

According to an alternative embodiment, bonding wires may be used to electrically connect the individual semiconductor device to the lead frame.

Next, according to one embodiment, at least parts of the semiconductor device, the solder bumps, and the lead frame are encapsulated in an encapsulant, while leaving the surface of the integral heat sink formed by the uppermost metallic layer exposed (step 530 of FIG. 5).

FIG. 6C illustrates portions of the semiconductor device and the lead frame 680 being encapsulated in a molding material 690, such as plastic. The integral heat sink in this case has three metallic layers 330, 340, 350. Thus, the third metallic layer 350 is exposed in order to release heat into the environment. Alternatively, if the integral heat sink only has two metallic layers 330, 340, then the second metallic layer 340 would be exposed. The step-like locking mechanism 372 resulted from dicing the wafer using two different sized saws helps lock the semiconductor device inside the encapsulant.

Finally, the encapsulated integrated circuit device and the lead frame are singulated into multiple packages (step 540 of FIG. 5). Each package contains an integrated circuit device with an integral heat sink on a lead frame and partially encapsulated in an encapsulant. Again, FIG. 6C illustrates such kind of a package.

The present invention has several advantages. For example, the integral heat sink formed on the back surface of the die increases the thermal dissipation while the IC device is in operation. In addition, using solder bumps with flip chip packaging increases current carrying capability.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description. They are not intended to be exhaustive or to limit the invention to the precise forms disclosed. It will be apparent to one of ordinary skill in the art that many modifications and variations are possible in view of the above teachings. For example, the semiconductor device shown in FIG. 6A may be packaged using any type of exposed die packaging or exposed heat sink packaging, such as dual inline package (DIP) or quad flat package (QFN). The thickness of the heat sink may be determined based on the thickness of the IC package.

The embodiments were chosen and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents.

What is claimed is:

1. A wafer level method for forming integral heat sinks on back surfaces of integrated circuit devices, the method comprising:
depositing a first metallic layer over a back surface of a wafer that contains a multiplicity of integrated circuit dice;
depositing a second metallic layer over the first metallic layer; and
dicing the wafer into a plurality of integrated circuit devices after the first and second metallic layers have been deposited, and
wherein for each of the plurality of integrated circuit devices, a portion of the first metallic layer and a portion of the second metallic layer combine to form a heat sink that is integrally formed with a die.

2. A method, as recited in claim 1, wherein depositing a first metallic layer over a back surface of a wafer comprises
sputtering a layer of a first metallic material over the back surface of the wafer.

3. A method, as recited in claim 1, wherein depositing a second metallic layer over the first metallic layer comprises
sputtering a first layer of a second metallic material over the first metallic layer, wherein the first layer of the second metallic material has a thickness in the range of approximately 1,000 to 1,500 ångströms; and
plating a second layer of the second metallic material over the first layer of the second metallic material, wherein the second layer of the second metallic material has a thickness in the range of approximately 10,000 to 50,000 ångströms.

4. A method, as recited in claim 1, further comprising:
depositing a third metallic layer over the second metallic layer prior to the dicing of the wafer, whereby after the dicing portions of the third metallic layer that overlie the die form part of the heat sink that is integrally formed with the die.

5. A method, as recited in claim 4, wherein depositing a third metallic layer over the second metallic layer comprises
sputtering a layer of a third metallic material over the second metallic layer.

6. A method, as recited in claim 4, wherein
the first metallic layer is one selected from a group consisting of titanium, titanium-tungsten, and nickel-vanadium,
the second metallic layer is one selected from a group consisting of copper and aluminum,
the third metallic layer is one selected from a group consisting of titanium, titanium-tungsten, and nickel-vanadium, and
the wafer is silicon.

7. A method, as recited in claim 4, wherein
the first metallic layer has a thickness in the range of approximately 300 to 900 ångströms;
the second metallic layer has a thickness in the range of approximately 10,000 to 60,000 ångströms; and
the third metallic has a thickness in the range of approximately 1,000 to 1,500 ångströms.

8. A method, as recited in claim 4, wherein the dicing of the wafer includes:
a first cutting operation that originates from the back surface of the wafer and cuts completely through the third, second, and first metallic layers and only partially cuts through the wafer at a first width; and
a second cutting operation that cuts completely through the wafer at a second width that is narrower than the first width, wherein the difference between the first width and the second width forms a step at the periphery of each integrated circuit device that may be used as a locking mechanism when the integrated circuit device is packaged.

9. A method, as recited in claim 8, wherein
the first width is between 1 to 1.2 millimeter, and the second width is between 0.8 to 1 millimeter, and
cutting partially through the wafer at a first width cuts through between 40% to 60% of the thickness of the wafer.

10. A method, as recited in claim 4, further comprising forming a plurality of solder bumps on an active surface of the wafer before dicing the wafer.

11. A method, as recited in claim 10, further comprising:
for each of the plurality of integrated circuit devices, connecting the integrated circuit device to a lead frame having a plurality of lead contacts by soldering each of the plurality of solder bumps to a corresponding lead contact of the plurality of lead contacts.

12. A method, as recited in claim 11, further comprising:
for each of the plurality of integrated circuit devices, encapsulating the die, the heat sink, the plurality of solder bumps, and at least a portion of the lead frame in an encapsulant while leaving a surface of the heat sink formed by the portion of the third metallic layer exposed.

13. A method, as recited in claim 4, further comprising:
before dicing the wafer, the first metallic layer, the second metallic layer, and the third metallic layer, mounting the wafer on a mounting tape, such that the back surface of the wafer faces away from the mounting tape; and
after dicing the wafer, the first metallic layer, the second metallic layer, and the third metallic layer, removing the plurality of integrated circuit devices from the mounting tape.

14. A semiconductor device, comprising:
a die having an active surface, a back surface, and a plurality of input/output (I/O) pads formed on the active surface;
a first metallic layer deposited over the back surface of the die; and
a second metallic layer deposited over the first metallic layer;
wherein the first metallic layer serves to adhere the second metallic layer to the die, and the first metallic layer and the second metallic layer combine to form a heat sink that is integrally formed with the die.

15. A semiconductor device, as recited in claim 14, further comprising:
a third metallic layer deposited over the second metallic layer,
wherein the third metallic layer helps protect the second metallic layer and combines with the first metallic layer and the second metallic layer to form the heat sink that is integrally formed with the die.

16. A semiconductor device, as recited in claim 15, wherein
the first metallic layer covers the entire back surface of the die,
the second metallic layer covers the entire first metallic layer, and
the third metallic layer covers the entire second metallic layer.

17. A semiconductor device, as recited in claim 15, wherein
the die is silicon.
the first metallic layer is one selected from a group consisting of titanium, titanium-tungsten, and nickel-vanadium,
the second metallic layer is one selected from a group consisting of copper and aluminum, and
the third metallic layer is one selected from a group consisting of titanium, titanium-tungsten, and nickel-vanadium.

18. A semiconductor device, as recited in claim 15, wherein
the first metallic layer has a thickness in the range of approximately 300 to 900 ångströms,
the second metallic layer has a thickness in the range of approximately 10,000 to 60,000 ångströms,
the third metallic has a thickness in the range of approximately 1,000 to 1,500 ångströms, and

19. A semiconductor device, as recited in claim 14, further comprising:
a plurality of solder bumps, each solder bump being formed on an associated I/O pad.

20. A semiconductor device, as recited in claim 14, further comprising:
a plurality of wires, each wire being formed on an associated I/O pad.

21. An integrated circuit package, comprising:
a semiconductor device comprising
a die having an active surface, a back surface, a plurality of I/O pads formed on the active surface, and a plurality of solder bumps each formed on an associated I/O pad,
a first metallic layer deposited over the back surface of the die, and
a second metallic layer deposited over the first metallic layer,
wherein
the first metallic layer serves to adhere the second metallic layer to the die, and
the first metallic layer and the second metallic layer combine to form a heat sink that is integrally formed with the die;
a lead frame having a plurality of lead contacts, wherein at least some of the lead contacts are soldered to associated I/O pads by their associated solder bumps; and
an encapsulant that encapsulates the die, the heat sink, the plurality of solder bumps, and at least a portion of the lead frame while leaving a surface of the heat sink formed by the second metallic layer exposed.

22. An integrated circuit package as recited in claim 21, wherein
the semiconductor device further comprising a third metallic layer deposited over the second metallic layer,
wherein
the third metallic layer helps protect the second metallic layer and combines with the first metallic layer and the second metallic layer to form the heat sink that is integrally formed with the die, and
the encapsulant leaves a surface of the heat sink formed by the third metallic layer exposed.

23. A semiconductor device, as recited in claim 22 wherein the semiconductor device has a first width that includes the third metallic layer, the second metallic layer, the first metallic, and a first portion of the die, a second width that includes a second portion of the die, wherein the first width is narrower than the second width, and the difference between the first width and the second width forms a step at the periphery of each semiconductor device that may be used as a locking mechanism for the semiconductor device when encapsulated.
